(19) United States
(12) Patent Application Publication
(10) Pub. No.: US 2023/0139063 A1
(43) Pub. Date: May 4, 2023

(54) IMPEDANCE-MATCHING MEMBRANE AND RADIO-WAVE-ABSORBING BODY

(71) Applicant: NITTO DENKO CORPORATION, Ibaraki-shi, Osaka (JP)

(72) Inventors: Yosuke Nakanishi, Osaka (JP); Hirokazu Tanaka, Tokyo (JP); Hironobu Machinaga, Osaka (JP)

(73) Assignee: NITTO DENKO CORPORATION, Ibaraki-shi, Osaka (JP)

(21) Appl. No.: 17/915,681

(22) PCT Filed: Mar. 8, 2021
(86) PCT No.: PCT/JP2021/008918

§ 371 Date: Sep. 29, 2022

(30) Foreign Application Priority Data
Mar. 30, 2020 (JP) 2020-061583

(51) Int. Cl. H01P 1/24; H01Q 17/00

(52) U.S. Cl. CPC H01P 1/24; H01Q 17/00

(57) ABSTRACT

An impedance matching film 10 includes a plurality of domains 11. Each of the domains 11 has a plurality of openings 12 having different shapes. The pluralities of openings 12 are periodically arranged in a specific direction along main surfaces 10f of the impedance matching film 10. Each of sizes of the domains 11 in the specific direction is 50 μm or more.

### TECHNICAL FIELD

The present invention relates to an impedance matching film and a radio wave absorber.

### BACKGROUND ART

Conventionally, the technology of matching the impedance of the surface of a radio wave absorber to the characteristic impedance of air by using a predetermined film has been known. Meanwhile, hitherto, there have been attempts to provide transparent radio wave absorbers.

For example, Patent Literature 1 describes a radio wave absorber having transparency. In the radio wave absorber, a mesh surface-like object made of conductive fibers is used as a resistive layer.

### CITATION LIST

### Patent Literature

Patent Literature 1: JP 2000-232320 A

### SUMMARY OF INVENTION

### Technical Problem

It is thought that impedance matching films having transparency will be required for sensing using high-frequency radio waves such as millimeter waves. In addition, it is thought that impedance matching films having transparency will be required for a wide range of technological fields such as 5th generation mobile communication systems (5G) and the Internet of Things (loT).

In order to provide an impedance matching film that can handle high-frequency radio waves and has transparency, it is conceivable to form a plurality of openings in an impedance matching film. In this case, diffraction and interference of light may cause an iridescent pattern in the impedance matching film. It is difficult to say that this is advantageous in terms of the appearance of the impedance matching film. In the technology described in Patent Literature 1, occurrence of such an iridescent pattern is not considered.

In view of such circumstances, the present invention provides an impedance matching film that can handle high-frequency radio waves, has transparency, and is advantageous in terms of reducing spatial variations in characteristics related to impedance matching while suppressing occurrence of an iridescent pattern.

### Solution to Problem

The present invention provides an impedance matching film including a plurality of domains, wherein

each of the domains has a plurality of openings having different shapes,

the pluralities of openings are periodically arranged in a specific direction along a main surface of the impedance matching film in the plurality of domains, and

each of sizes of the domains in the specific direction is 50 μm or more.

In addition, the present invention provides a radio wave absorber including:

the above impedance matching film;

a reflector for reflecting radio waves; and

a dielectric layer disposed between the impedance matching film and the reflector in a thickness direction of the impedance matching film.

### Advantageous Effects of Invention

The above impedance matching film can handle high-frequency radio waves, has transparency, and is advantageous in terms of suppressing occurrence of an iridescent pattern and spatial variations in characteristics related to impedance matching.

### BRIEF DESCRIPTION OF THE DRAWINGS

FIG. 1 is a plan view showing an example of an impedance matching film according to the present invention.

FIG. 2 is a plan view showing a domain in the impedance matching film shown in FIG. 1.

FIG. 3 is a cross-sectional view taken along a line III-III shown in FIG. 1.

FIG. 4A is a plan view showing another example of the domain.

FIG. 4B is a plan view showing still another example of the domain.

FIG. 4C is a plan view showing still another example of the domain.

FIG. 4D is a plan view showing still another example of the domain.

FIG. 4E is a plan view showing still another example of the domain.

FIG. 4F is a plan view showing still another example of the domain.

FIG. 4G is a plan view showing still another example of the domain.

FIG. 4H is a plan view showing still another example of the domain.

FIG. 5A is a cross-sectional view showing an example of a radio wave absorber according to the present invention.

FIG. 5B is a cross-sectional view showing a modification of the radio wave absorber according to the present invention.

FIG. 5C is a cross-sectional view showing another modification of the radio wave absorber according to the present invention.

FIG. 6 is a cross-sectional view showing another example of the radio wave absorber according to the present invention.

### DESCRIPTION OF EMBODIMENTS

If an impedance matching film has a plurality of openings, this is advantageous in terms of imparting transparency to the impedance matching film. For example, if such an impedance matching film can handle high-frequency radio waves, the value of the impedance matching film can be further enhanced. Therefore, the present inventors have studied intensively on an impedance matching film that can handle high-frequency radio waves and has a plurality of openings. In the course of this study, the present inventors have noticed that, when openings having a predetermined size are formed at equal intervals in an impedance matching film, an iridescent pattern is likely to occur due to diffraction and interference of light. The present inventors have further studied and found that occurrence of an iridescent pattern can be suppressed by forming a plurality of openings having different shapes in an impedance matching film. Meanwhile, according to the study by the present inventors, in order to suppress spatial variations in impedance matching, it is also important that the areas of the openings do not considerably vary spatially. Therefore, the present inventors have conducted a great deal of trial and error, have found a condition for suppressing occurrence of an iridescent pattern in an impedance matching film and suppressing spatial variations in characteristics related to impedance matching, and have conceived of an impedance matching film according to the present invention. As used herein, “transparency” means transparency to visible light, unless otherwise described.

Embodiments of the present invention will be described with reference to the drawings. The present invention is not limited to the following embodiments.

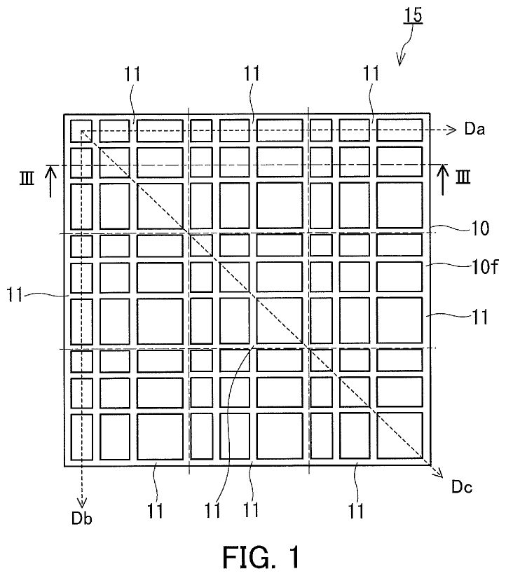

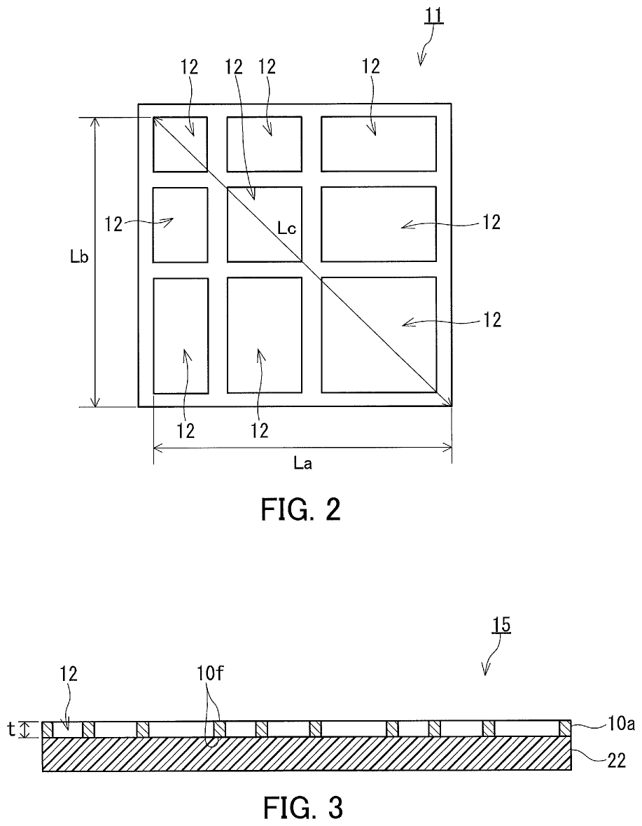

As shown in FIG. 1, an impedance matching film 10 includes a plurality of domains 11. As shown in FIG. 2, each domain 11 has a plurality of openings 12 having different shapes. The pluralities of openings 12 are periodically arranged in a specific direction along main surfaces 10f of the impedance matching film 10. The size of each domain 11 in the specific direction is 50 μm or more. The domain 11 is a region that has a plurality of openings 12 having different shapes and is delimited, for example, on the basis of the periodicity of the periodic arrangement in a specific direction of the pluralities of openings 12 having different shapes. As used herein, “having different shapes” means that, even when one of two openings 12 to be compared is shifted parallel, the one of the two openings 12 does not completely overlap the other of the two openings 12. For example, when one of two openings 12 to be compared is shifted parallel so as to overlap the other of the two openings 12, if the area of the overlapping portion of the two openings 12 is 90% or less of the area of the one of the two openings 12, the one of the two openings 12 can be regarded as not completely overlapping the other of the two openings 12. The size of each domain 11 in the specific direction is the distance between the ends of the pluralities of openings 12 in the specific direction of the two domains 11 adjacent to each other in the specific direction.

In an impedance matching film, when openings having a predetermined size and the same shape are formed at equal intervals, an iridescent pattern is likely to occur due to diffraction and interference of light. On the other hand, in the impedance matching film 10, since the pluralities of openings 12 having different shapes are periodically arranged in the specific direction, the sizes of the openings 12 in the specific direction vary periodically. In addition, since the impedance matching film 10 has the plurality of domains 11 such that the pluralities of openings 12 are periodically arranged in the specific direction along the main surfaces 10f of the impedance matching film 10, the areas of the openings 12 do not considerably vary spatially. Therefore, in the impedance matching film 10, spatial variations in characteristics related to impedance matching is easily suppressed.

In the impedance matching film 10, the specific direction may include a plurality of alignment directions intersecting each other. The pluralities of openings 12 are periodically arranged, for example, in three alignment directions Da, Db, and Dc intersecting each other. Accordingly, in a wide range of the impedance matching film 10, occurrence of an iridescent pattern can be suppressed, and spatial variations in characteristics related to impedance matching can be reduced. The plurality of alignment directions intersecting each other may be orthogonal to each other. For example, any one of a size La of each domain 11 in the alignment direction Da, a size Lb of each domain 11 in the alignment direction Db, and a size Lc of each domain 11 in the alignment direction Dc is 50 μm or more. Desirably, the sizes La, Lb, and Lc are 50 μm or more.

A frame defining the pluralities of openings 12 may, for example, form a plurality of linear patterns aligned in the specific direction such that the linear patterns appear in the alignment direction Da and the alignment direction Db, or may form a plurality of dotted patterns aligned in the specific direction such that the dotted patterns appear in the alignment direction Dc. In either case, since the size of each domain 11 in the specific direction is 50 μm or more, occurrence of an iridescent pattern can be suppressed. Meanwhile, in the case where the frame defining the pluralities of openings 12 forms linear patterns in the specific direction, the size of each domain 11 in the specific direction is more desirably 50 μm or more in terms of suppressing occurrence of an iridescent pattern.

As shown in FIG. 2, for example, the openings 12 are adjacent to each other in each domain 11. In other words, the shapes of the openings 12 adjacent to each other are different from each other. Accordingly, occurrence of an iridescent pattern is more easily suppressed in the impedance matching film 10.

The upper limit of the size of each domain 11 in the specific direction is not limited to a specific value.

An average value PA of the perimeters of the plurality of openings 12 included in each domain 11 is not limited to a specific value. The average value P_{A} is, for example, 5000 μm or less. Accordingly, the impedance matching film 10 easily handles high-frequency radio waves. The average value P_{A} can be determined by dividing the total of all the perimeters of the plurality of openings 12 included in each domain 11 by the number of the plurality of openings 12.

The average value P_{A} is desirably 4000 μm or less, more desirably 3000 μm or less, further desirably 2000 μm or less, and particularly desirably 1000 μm or less. The average value PA is, for example, 10 μm or more, and may be 20 μm or more, may be 50 μm or more, or may be 100 μm or more.

As shown in FIG. 2, all the shapes of the plurality of openings 12 included in the domain 11 may be different from each other. Accordingly, occurrence of an iridescent pattern is more easily suppressed in the impedance matching film 10.

The number of openings 12 included in each domain 11 is not limited to a specific value. The number of openings 12 included in each domain 11 is, for example, 3 or more, and may be 4 or more, or may be 5 or more. The number of openings 12 may be a square number or an integer other than a square number.

The shape of each domain 11 is not limited to a specific shape. The shape of each domain 11 is, for example, a polygonal shape formed such that the domains 11 having the same shape exist on a plane without gaps therebetween. The shape of each domain 11 is, for example, a square shape or a rectangular shape.

The sheet resistance of the impedance matching film 10 is not limited to a specific value. The impedance matching film 10 has, for example, a sheet resistance of 200 to 1000 Ω/□. Accordingly, good impedance matching for high-frequency radio waves is easily performed by the impedance matching film 10. The sheet resistance of the impedance matching film 10 can be measured, for example, according to the eddy current method.

The sheet resistance of the impedance matching film 10 may be 250 Ω/□ or more, may be 300 Ω/□ or more, or may be 350 Ω/□ or more. The sheet resistance of the impedance matching film 10 may be 950 Ω/□ or less, may be 900 Ω/□ or less, or may be 850 Ω/□0 or less.

A thickness t of the impedance matching film 10 is not limited to a specific value. The thickness t is, for example, 5 nm or more. In this case, the sheet resistance of the impedance matching film 10 is less likely to vary over a long period of time, and the impedance matching film 10 easily exhibits high durability.

The thickness t of the impedance matching film 10 may be 10 nm or more or may be 15 nm or more. The thickness t is, for example, 500 nm or less. Accordingly, warpage of the impedance matching film 10 is easily suppressed, so that cracks are less likely to occur in the impedance matching film 10. The thickness t may be 450 nm or less or may be 400 nm or less.

An opening ratio in the impedance matching film 10 is not limited to a specific value. The opening ratio in the impedance matching film 10 may be, for example, 40% or more. On the other hand, the opening ratio in the impedance matching film 10 is desirably 65% or more. Accordingly, the impedance matching film 10 easily has high transparency. The opening ratio in the impedance matching film 10 is a ratio Sa/(Sa+Sb) of an opening area Sa of the pluralities of opening 12 to a sum Sa+Sb of the opening area Sa of the pluralities of opening 12 and an area Sb of the non-opening portion of the impedance matching film 10 when the impedance matching film 10 is viewed in a plan view.

The opening ratio in the impedance matching film 10 is more desirably 70% or more and further desirably 75% or more. The opening ratio in the impedance matching film 10 is, for example, 99% or less, and may be 98% or less, or may be 97% or less.

The shapes of the pluralities of openings 12 are not limited to specific shapes. The pluralities of openings 12 each have, for example, a square shape or a rectangular shape in a plan view.

The material forming the impedance matching film 10 is not limited to a specific material. The material forming the impedance matching film 10 may be an inorganic material such as metals, alloys, and metal oxides, or may be an organic material such as electroconductive polymers and carbon nanotubes.

The impedance matching film 10 may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

As shown in FIG. 3, the impedance matching film 10 may be formed, for example, on one main surface of a substrate 22. In this case, the impedance matching film 10 can be provided by an impedance matching film-attached film 15. The impedance matching film 10 may be provided alone without using the substrate 22.

The substrate 22 serves, for example, as a support for supporting the impedance matching film 10. The impedance matching film 10 in the impedance matching film-attached film 15 can be produced, for example, by forming the plurality of openings 11 by laser processing, etching, or the like in a non-porous film formed on one main surface of the substrate 22 by a film forming method such as sputtering. In some cases, a non-porous film for the impedance matching film 10 may be formed by a film forming method such as ion plating or coating (for example, bar coating).

The substrate 22 has, for example, a thickness of 10 to 150 μm, and desirably has a thickness of 15 to 100 μm. Accordingly, the flexural rigidity of the substrate 22 is low, and it is possible to suppress wrinkling or deformation of the substrate 22 when forming the impedance matching film 10.

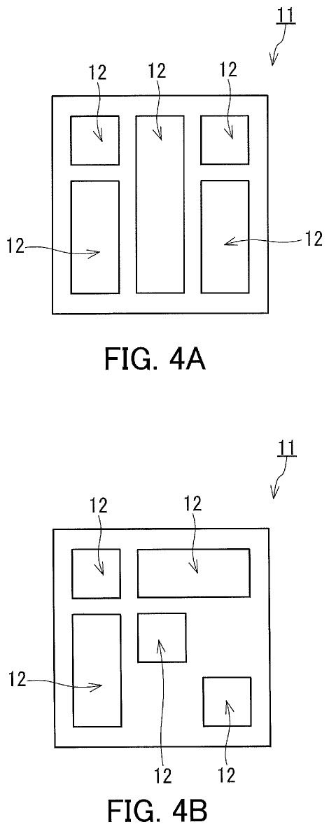

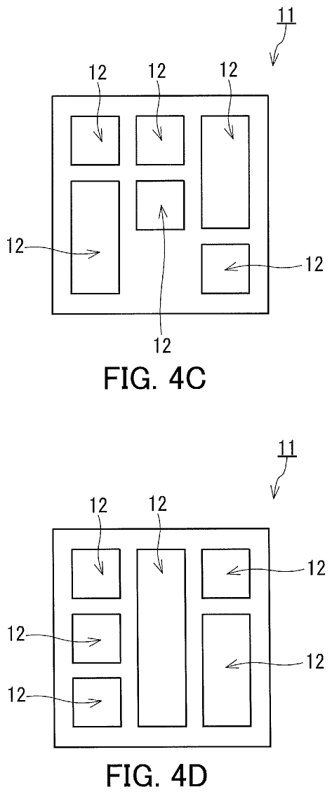

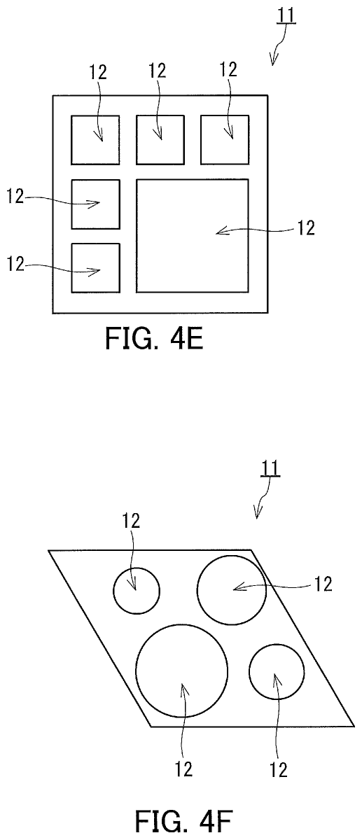

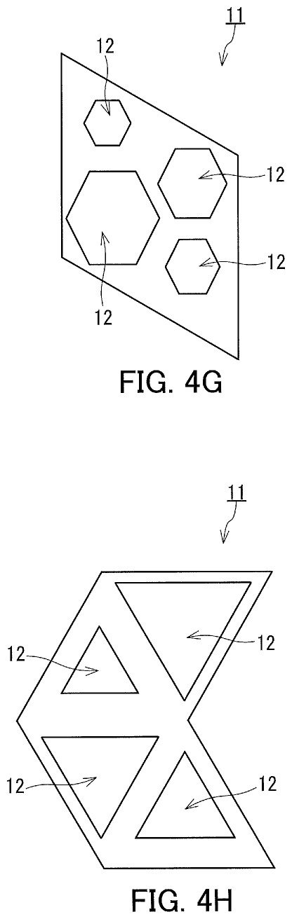

Each domain 11 may be configured, for example, as shown in FIG. 4A, FIG. 4B, FIG. 4C, FIG. 4D, FIG. 4E, FIG. 4F, FIG. 4G, and FIG. 4H.

As shown in FIG. 4A to FIG. 4E, the domain 11 may have openings 12 having the same shape as long as the domain 11 has a plurality of openings 12 having different shapes. In addition, as shown in FIG. 4C to FIG. 4E, openings 12 having the same shape may be adjacent to each other. Even in such a case, occurrence of an iridescent pattern is easily suppressed as compared to an impedance matching film having only openings having the same shape and formed at equal intervals as the openings.

As shown in FIG. 4F, in the domain 11, the shape of each opening 12 may be a circular shape. In this case, the shape of the domain 11 is, for example, a parallelogram shape. On the other hand, the shape of the domain 11 may be a square shape or a rectangular shape.

As shown in FIG. 4G, in the domain 11, the shape of each opening 12 may be a regular hexagonal shape. In this case, the shape of the domain 11 is, for example, a parallelogram shape. On the other hand, the shape of the domain 11 may be a square shape or a rectangular shape.

As shown in FIG. 4H, in the domain 11, the shape of each opening 12 may be a triangular shape. In this case, the shape of the domain 11 is, for example, a hexagonal shape formed by linearly symmetrically arranging a pair of parallelograms such that the parallelograms share one side.

In the domain 11, the shape of each opening 11 may be another polygonal shape or an elliptical shape. The shape of the domain 11 may be another polygonal shape.

As shown in FIG. 1, the impedance matching film 10 is formed, for example, by only one type of the domains 11. The impedance matching film 10 may be formed by two or more types of domains 11. In this case, in the specific direction, the same type of domains 11 may be adjacent to each other, or a plurality of types of domains 11 may alternately exist.

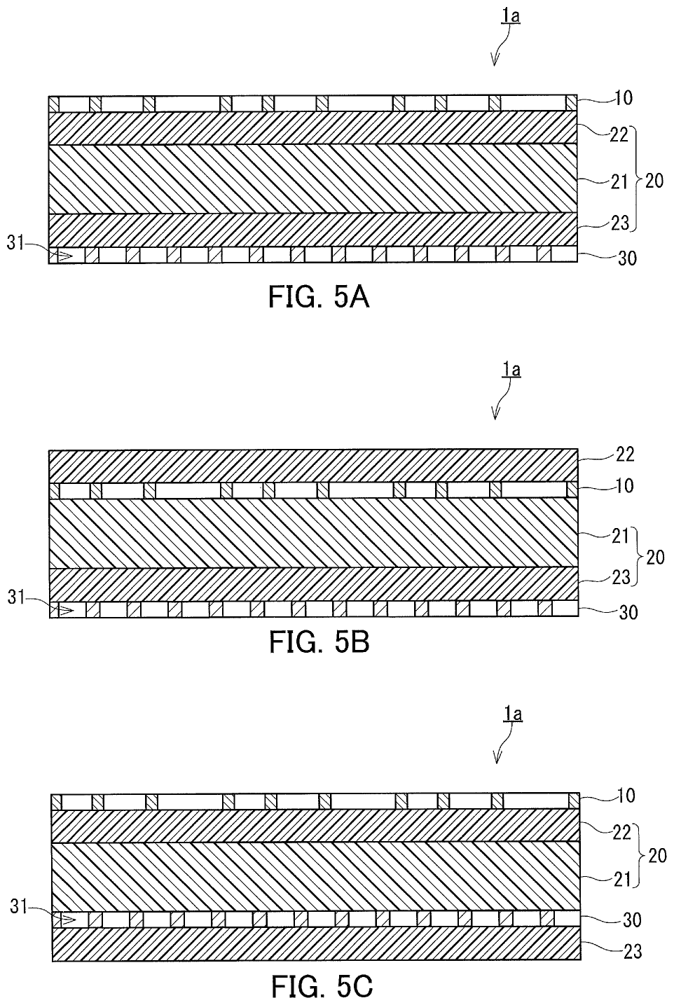

As shown in FIG. 5A, a radio wave absorber 1a can be provided, for example, using the impedance matching film 10. The radio wave absorber 1a includes the impedance matching film 10, a reflector 30 for reflecting radio waves, and a dielectric layer 20. The dielectric layer 20 is disposed between the impedance matching film10 and the reflector 30 in the thickness direction of the impedance matching film 10.

The radio wave absorber 1a is, for example, a λ/4 radio wave absorber. The radio wave absorber 1a is designed such that, when radio waves of a wavelength λ₀ to be absorbed by the radio wave absorber 1a are incident on the radio wave absorber 1a, radio waves resulting from reflection on the front surface of the impedance matching film 10 (front surface reflection) and radio waves resulting from reflection on the reflector 30 (back surface reflection) interfere with each other. In the λ/4 radio wave absorber, as shown in the following equation (1), the wavelength λ₀ of the radio waves to be absorbed is determined according to a thickness t of the dielectric layer and a relative permittivity εᵣ of the dielectric layer. That is, the radio waves of the wavelength to be absorbed can be set by adjusting the relative permittivity and the thickness of the dielectric layer as appropriate. In the equation (1), sqrt(εᵣ) means the square root of the relative permittivity εᵣ.

λ₀=4t×sqrt(εᵣ) Equation (1)

The radio wave absorber 1a is configured to be able to absorb radio waves in a predetermined frequency range of 10 GHz or more, for example. Examples of the frequency ranges of radio waves that can be absorbed by the radio wave absorber 1a are as follows. The following radio waves are under consideration for use as radio waves for 5G in various countries.
27.5 to 29.5 GHz
27.5 to 28.35 GHz
24.25 to 24.45 GHz
24.75 to 25.25 GHz
37 to 38.6 GHz
38.6 to 40 GHz
47.2 to 48.2 GHz
64 to 71 GHz
24.25 to 27.5 GHz
40.5 to 43.5 GHz
66 to 71 GHz
24.75 to 27.5 GHz
37 to 42.5 GHz
27.5 to 29.5 GHz
31.8 to 33.4 GHz
37 to 40.5 GHz

Other examples of the frequency ranges of the radio waves that can be absorbed by the radio wave absorber 1a are as follows. The following radio waves can be used as radio waves for a millimeter wave radar.
21.65 to 26.65 GHz
60 to 61 GHz
76 to 77 GHz
77 to 81 GHz
94.7 to 95 GHz
139 to 140 GHz

The radio wave absorber 1a has, for example, an absorption peak frequency of 10 GHz or more. This allows absorption of desired high-frequency radio waves.

An absorption peak frequency f_{P} is the frequency of a radio wave whose return loss |S| is the maximum for the radio wave absorber 1a. The return loss |S| is the absolute value of S calculated by the following equation (2). In the equation (2), P₀ is the power of transmitted radio waves when radio waves are incident on a measurement target at a predetermined incident angle, and Pᵢ is the power of received radio waves in this case. The value of the return loss |S| for the radio wave absorber 1a is determined, for example, with the value of the return loss |S| when radio waves are incident on a plate of a reference metal such as aluminum at a predetermined incident angle being regarded as 0 dB. In the radio wave absorber 1a, front surface reflection of radio waves having the absorption peak frequency fₚ occurs properly, and the radio wave absorber 1a can satisfactorily absorb the radio waves having the absorption peak frequency f_{P}.

S[dB]=10×log|Pᵢ/P₀| Equation (2)

The radio wave absorber 1a exhibits, for example, a return loss of 10 dB or more, and desirably exhibits a return loss of 20 dB or more, in a predetermined frequency range of 10 GHz or more.

The reflector 30 is not limited to a specific form as long as the radio waves to be absorbed can be reflected. The reflector 30 is, for example, a transparent conductive film. In this case, the reflector 30 has transparency, and the entire radio wave absorber 1a is easily made transparent. The material forming the transparent conductive film may be an inorganic material such as metals including aluminum, etc., alloys, and metal oxides, or may be an organic material such as electroconductive polymers and carbon nanotubes. The reflector 30 may be an opaque conductive film. The material forming such a conductive film may be an inorganic material such as metals including aluminum, etc., alloys, and metal oxides, or may be an organic material such as electroconductive polymers and carbon nanotubes.

The transparent conductive film has, for example, a plurality of openings 31 formed along main surfaces of the transparent conductive film. This configuration allows the reflector 30 to properly reflect radio waves to be absorbed and makes it easier for the reflector 30 to have desired transparency. The transparent conductive film may be a non-porous film.

In the case where the reflector 30 has the plurality of openings 31, the impedance matching film 10 may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

The shapes of the plurality of openings 31 in the reflector 30 are not limited to specific shapes. Each of the shapes of the plurality of openings 31 may be, for example, a triangular shape, a quadrilateral shape such as a square shape and a rectangular shape, a hexagonal shape, another polygonal shape, a circular shape, or an elliptical shape in a plan view.

The arrangement of the plurality of openings 31 in the reflector 30 is not limited to a specific arrangement. The plurality of openings 31 may be arranged such that, for example, the centers of the plurality of openings 31 form a planar lattice such as a square lattice and a parallelogram lattice.

The dielectric layer 20 has, for example, a relative permittivity of 2.0 to 20.0. In this case, it is easy to adjust the thickness of the dielectric layer 20, and it is easy to adjust the radio wave absorption performance of the radio wave absorber 1a. The relative permittivity of the dielectric layer 20 is, for example, a relative permittivity at 10 GHz measured according to the cavity resonance method.

The dielectric layer 20 is formed, for example, from a predetermined polymer. The dielectric layer 20 contains, for example, at least one polymer selected from the group consisting of ethylene-vinyl acetate copolymer, vinyl chloride resin, urethane resin, acrylic resin, acrylic urethane resin, acrylic-based elastomer, polyethylene, polypropylene, silicone, polyethylene terephthalate, polyethylene naphthalate, polycarbonate, polyimide, and cycloolefin polymer. In this case, it is easy to adjust the thickness of the dielectric layer 20, and the production cost of the radio wave absorber 1a can be kept low. The dielectric layer 20 can be produced, for example, by hot-pressing a predetermined resin composition.

The dielectric layer 20 may be formed as a single layer, or may be formed of a plurality of layers made of the same material or different materials. In the case where the dielectric layer 20 has n layers (n is an integer equal to or greater than 2), the relative permittivity of the dielectric layer 20 is determined as follows, for example. A relative permittivity εᵢ of each layer is measured (i is an integer from 1 to n). Next, εᵢ×(tᵢ/T) is obtained by multiplying the measured relative permittivity εᵢ of each layer by the ratio of a thickness tᵢ of the layer to a total thickness T of the dielectric layer 20. The relative permittivity of the dielectric layer 20 can be determined by adding up εᵢ×(tᵢ/T) of all the layers.

As shown in FIG. 5A, the dielectric layer 20 includes, for example, a first layer 21, a second layer 22, and a third layer 23. The first layer 21 is disposed between the second layer 22 and the third layer 23. The first layer 21 contains, for example, at least one polymer selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer.

In the radio wave absorber 1a, the second layer 22 serves as a substrate for the impedance matching film 10. The second layer 22 is disposed, for example, at a position closer to the reflector 30 than the impedance matching film 10 is. As shown in FIG. 5B, the second layer 22 may be disposed at a position farther from the reflector 30 than the impedance matching film 10 is. In this case, the dielectric layer 20 is composed of the first layer 21 and the third layer 23. In this case, the impedance matching film 10 and the dielectric layer 20 are protected by the second layer 22, and the radio wave absorber 1a has high durability. In this case, for example, the impedance matching film 10 may be in contact with the first layer 21. The material of the second layer 22 is, for example, polyethylene terephthalate (PET), polyethylene naphthalate (PEN), acrylic resin (PMMA), polycarbonate (PC), polyimide (PI), or cycloolefin polymer (COP). Among them, the material of the second layer 22 is desirably PET in terms of the balance among good heat resistance, dimensional stability, and manufacturing cost.

In the radio wave absorber 1a, the third layer 23 supports the reflector 30, for example. In this case, the reflector 30 may be produced, for example, by forming a film on the third layer 23 using a method such as sputtering, ion plating, or coating (for example, bar coating). Furthermore, the plurality of openings 31 may be formed by laser processing, etching, or the like. As shown in FIG. 5A, the third layer 23 is disposed, for example, at a position closer to the impedance matching film 10 in the radio wave absorber 1a than the reflector 30 is, and forms a part of the dielectric layer 20. As shown in FIG. 5C, the third layer 23 may be disposed at a position farther from the impedance matching film 10 than the reflector 30 is. In this case, for example, the reflector 30 is in contact with the first layer 21.

As the material of the third layer 23, for example, the materials exemplified as the material of the second layer 22 can be used. The material of the third layer 23 may be the same as or different from the material of the second layer 22. The material of the third layer 23 is desirably PET in terms of the balance among good heat resistance, dimensional stability, and manufacturing cost.

The third layer 23 has, for example, a thickness of 10 to 150 μm, and desirably has a thickness of 15 to 100 μm. Accordingly, the flexural rigidity of the third layer 23 is low, and it is possible to suppress wrinkling or deformation of the third layer 23 when forming the reflector 30. The third layer 23 may be omitted in some cases.

The first layer 21 may be composed of a plurality of layers. In particular, in the case where the first layer 21 is in contact with at least one of the impedance matching film 10 and the reflector 30 as shown in FIG. 5B or FIG. 5C, the first layer 21 can be composed of a plurality of layers.

The first layer 21 may have adhesiveness, or may not necessarily have adhesiveness. In the case where the first layer 21 has adhesiveness, an adhesive layer may be disposed in contact with at least one of both main surfaces of the first layer 21, or adhesive layers may not necessarily be disposed in contact with both main surfaces of the first layer 21, respectively. In the case where the first layer 21 does not have adhesiveness, adhesive layers are desirably disposed in contact with both main surfaces of the first layer 21, respectively. In the case where the dielectric layer 20 includes the second layer 22, even if the second layer 22 does not have adhesiveness, adhesive layers may not necessarily be disposed in contact with both main surfaces of the second layer 22, respectively. In this case, an adhesive layer can be disposed in contact with one main surface of the second layer 22. In the case where the dielectric layer 20 includes the third layer 23, even if the third layer 23 does not have adhesiveness, adhesive layers may not necessarily be disposed in contact with both main surfaces of the third layer 23, respectively. In this case, an adhesive layer can be disposed in contact with at least one main surface of the third layer 23. Each adhesive layer contains, for example, a rubber-based adhesive agent, an acrylic-based adhesive agent, a silicone-based adhesive agent, or a urethane-based adhesive agent. The thickness of each adhesive layer containing the adhesive agent is not limited to a specific value, and is, for example, 3 to 50 μm, and desirably 5 to 30 μm.

The radio wave absorber la may contain at least one of a dielectric loss material and a magnetic loss material. In other words, the radio wave absorber 1a may be a dielectric loss radio wave absorber or a magnetic loss radio wave absorber. The dielectric layer 20 may contain at least one of a dielectric loss material and a magnetic loss material. The material forming the impedance matching film 10 may be magnetic.

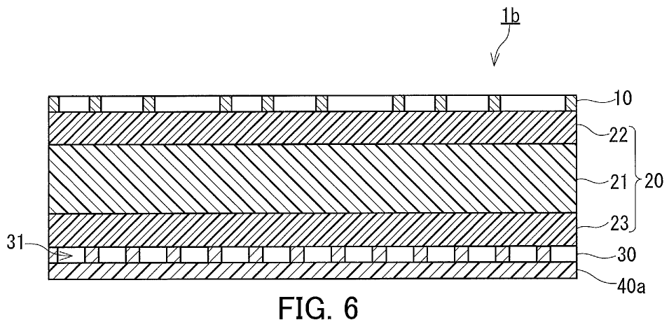

The radio wave absorber 1a can be modified in various respects. For example, the radio wave absorber 1a may be modified into a radio wave absorber 1b shown in FIG. 6. The radio wave absorber 1b is configured in the same manner as the radio wave absorber 1a except for the portions that are particularly described. The components, of the radio wave absorber 1b, identical to or corresponding to the components of the radio wave absorber 1a are indicated by the same reference characters, and the detailed descriptions thereof are omitted. The descriptions given for the radio wave absorber 1a are also applicable to the radio wave absorber 1b unless there is a technical inconsistency.

As shown in FIG. 6, the radio wave absorber 1b further includes an adhesive layer 40a. In the radio wave absorber 1b, the reflector 30 is disposed between the dielectric layer 20 and the adhesive layer 40a.

For example, the radio wave absorber 1b can be adhered to a predetermined article by pressing the radio wave absorber 1b against the article with the adhesive layer 40a brought into contact with the article. Accordingly, a radio wave absorber-attached article can be obtained.

The adhesive layer 40a contains, for example, a rubber-based adhesive agent, an acrylic-based adhesive agent, a silicone-based adhesive agent, or a urethane-based adhesive agent. The radio wave absorber 1b may further include a release liner (not shown). In this case, the release liner covers the adhesive layer 40a. The release liner is typically a film that can maintain the adhesive strength of the adhesive layer 40a when covering the adhesive layer 40a and that can easily be peeled from the adhesive layer 40a. The release liner is, for example, a film made of polyester resin such as PET. By peeling the release liner, the adhesive layer 40a becomes exposed, allowing the radio wave absorber 1b to be adhered to an article.

### EXAMPLES

Hereinafter, the present invention will be described in more detail by means of Example. The present invention is not limited to the following Example. First, evaluation methods for the Example and Comparative Example will be described.

[TEM Observation]

Cross-sectional observation samples of a non-porous film according to each of the Example and the Comparative Example and an alloy film in an alloy film-attached film according to each of the Example and the Comparative Example were prepared using a focused ion beam processing observation apparatus (product name: FB-2000A, manufactured by Hitachi High-Tech Corporation). Then, the cross-sectional observation samples were observed using a field emission transmission electron microscope (product name: HF-2000, manufactured by Hitachi High-Tech Corporation), and the thickness of the non-porous film according to each of the Example and the Comparative Example was measured. The thickness of the non-porous film was regarded as the thickness of the alloy film in the alloy film-attached film according to each of the Example and the Comparative Example.

[Sheet Resistance]

The sheet resistance of the alloy film in the alloy film-attached film according to each of the Example and the Comparative Example was measured by the eddy current method according to JIS Z 2316 using a non-contact type resistance measurement device NC-80LINE manufactured by NAPSON CORPORATION. The results are shown in Table 2.

[Appearance Check]

In a state where the alloy film-attached film of the sample according to each of the Example and the Comparative Example was irradiated with light from a white light source, whether or not an iridescent pattern was observed was checked. When an iridescent pattern was not observed, the film was evaluated as “A”, and when an iridescent pattern was observed, the film was evaluated as “X”. The results are shown in Table 2.

[Radio Wave Absorption Performance]

With reference to JIS R 1679: 2007, radio waves having frequencies of 60 to 90 GHz were made incident at an incident angle of 0° on the sample according to each of the Example and the Comparative Example fixed to a sample holder, using a vector network analyzer manufactured by ANRITSU CORPORATION, and a return loss |S| at each frequency was determined according to the above equation (2). Instead of the sample according to each of the Example and the Comparative Example, an aluminum plate was fixed to the sample holder, a return loss |S| when radio waves were incident perpendicularly on the plate was regarded as 0 dB, and the return loss |S| of each sample was determined. The plate had a face dimension of 30 cm square, and the thickness of the plate was 5 mm. The maximum value of the return loss |S| in each sample and the frequency (absorption peak frequency fₚ) at which the maximum value was exhibited were determined. When the maximum value of the return loss |S| is 10 dB or more, the sample can be evaluated to have good radio wave absorption performance. The results are shown in Table 2.

### Example 1

DC magnetron sputtering was performed using an Al (aluminum) target material and an Si (silicon) target material and using argon gas as a process gas, to form an Al—Si alloy film on a PET film. In the DC magnetron sputtering, discharge involving the Al (aluminum) target material and discharge involving the Si (silicon) target material were performed simultaneously. Thus, a non-porous film according to Example 1 was formed on the PET film. The non-porous film had a thickness of 30 nm. Next, using a metal laser patterning machine, openings were formed in the non-porous film according to Example 1 such that a domain having 16 openings and having a square shape with 280 pm square was repeatedly formed along a main surface of the non-porous film. In each domain, 16 openings each having a square or rectangular shape with a dimension shown in Table 1 were formed in a matrix. In each cell of Table 1, the value on the left side indicates the dimension of the opening in the direction extending along the rows of the matrix, and the value on the right side indicates the dimension of the opening in the direction along the columns of the matrix. The distance between the nearest openings was 10 μm.

TABLE 1

| | Column | | | |
|---|---|---|---|---|
| Row | First column | Second column | Third column | Fourth column |
| First row | 30 μm, 30 μm | 30 μm, 50 μm | 30 μm, 70 μm | 30 μm, 90 μm |
| Second row | 50 μm, 30 μm | 50 μm, 50 μm | 50 μm, 70 μm | 50 μm, 90 μm |
| Third row | 70 μm, 30 μm | 70 μm, 50 μm | 70 μm, 70 μm | 70 μm, 90 μm |
| Fourth row | 90 μm, 30 μm | 90 μm, 50 μm | 90 μm, 70 μm | 90 μm, 90 μm |

DC magnetron sputtering was performed using an ITO target material containing 10 weight % of SnO₂ and using argon and oxygen as process gases, to form an ITO film on a PET film. Then, the ITO film was annealed under the condition of a temperature of 150° C. for 1 hour to polycrystallize the ITO, to obtain a reflector-attached film. The sheet resistance of the reflector of the reflector-attached film was 20 Ω/□. Next, an acrylic resin having a relative permittivity of 2.6 was molded so as to have a thickness of 550 pm, to obtain an acrylic resin layer A. The alloy film-attached film according to Example 1 was put on the acrylic resin layer A such that the alloy film of the alloy film-attached film according to Example 1 was in contact with the acrylic resin layer A. Next, the reflector-attached film was put on the acrylic resin layer A such that the ITO in the reflector-attached film was in contact with the acrylic resin layer A. Thus, a sample according to Example 1 was obtained.

### Comparative Example 1

A non-porous film according to Comparative Example 1 was formed on a PET film in the same manner as Example 1. The thickness of the non-porous film was 30 nm. Next, using a metal laser patterning machine, a plurality of square-shaped openings were formed at equal intervals in the non-porous film according to Comparative Example 1 so as to form a square lattice, to obtain an alloy film-attached film according to Comparative Example 1. In a plan view of the alloy film-attached film according to Comparative Example 1, the size of each opening in the direction in which the plurality of openings were arranged at equal intervals was 35 μm, and the distance between the nearest openings was 10 μm.

A sample according to Comparative Example 1 was obtained in the same manner as Example 1, except that the alloy film-attached film according to Comparative Example 1 was used instead of the alloy film-attached film according to Example 1.

TABLE 2

| | Size of | Average | Distance | | | Absorption | Maximum |
|---|---|---|---|---|---|---|---|
| | domain | value of | between | | Presence/ | peak | value of |
| | in specific | perimeters | nearest | Sheet | absence of | frequency | return |
| | direction | of openings | openings | resistance | iridescent | fp | loss |
| | [μm] | [μm] | [μm] | [Ω/□] | pattern | [GHz] | [dB] |
| Ex. 1 | 280 | 240 | 10 | 400 | A | 77 | 40 |
| Comp. | — | 140 | 10 | 400 | X | 77 | 40 |
| Ex. 1 | | | | | | | |

1. An impedance matching film comprising a plurality of domains, wherein
each of the domains has a plurality of openings having different shapes,
the pluralities of openings are periodically arranged in a specific direction along a main surface of the impedance matching film in the plurality of domains, and
each of sizes of the domains in the specific direction is 50 μm or more.

2. The impedance matching film according to claim 1, wherein the specific direction includes a plurality of alignment directions intersecting each other.

3. The impedance matching film according to claim 1,
wherein the openings in each of the domains are adjacent to each other.

4. The impedance matching film according to claim 1 wherein an average value of perimeters of the plurality of openings included in each of the domains is 5000 μm or less.

5. The impedance matching film according to claim 1, wherein all shapes of the plurality of openings included in each of the domains are different from each other.

6. The impedance matching film according to claim 1, wherein the impedance matching film has a sheet resistance of 200 to 1000 Ω/□.

7. A radio wave absorber comprising:
the impedance matching film according to claim 1;
a reflector for reflecting radio waves; and
a dielectric layer disposed between the impedance matching film and the reflector in a thickness direction of the impedance matching film.

8. The radio wave absorber according to claim 7, wherein the reflector is a transparent conductive film.

9. The radio wave absorber according to claim 7, wherein the radio wave absorber has an absorption peak frequency of 10 GHz or more.
